(19) United States
(12) Patent Application Publication
(10) Pub. No.: US 2026/0018575 A1
(43) Pub. Date: Jan. 15, 2026

(54) CHIP STRUCTURE, AND SEMICONDUCTOR PACKAGE INCLUDING THE SAME

(71) Applicant: SAMSUNG ELECTRONICS CO., LTD., Suwon-si (KR)

(72) Inventors: Jing Cheng Lin, Suwon-si (KR); Jung Hua Chang, Suwon-si (KR)

(73) Assignee: SAMSUNG ELECTRONICS CO., LTD, Suwon-si (KR)

(21) Appl. No.: 19/081,732

(22) Filed: Mar. 17, 2025

(30) Foreign Application Priority Data
Jul. 12, 2024 (KR) 10-2024-0092587

(51) Int. Cl. H01L 25/16; G02B 6/42; H01L 23/00; H01L 23/31; H01L 23/538; H10F 39/00; H10F 39/95

(52) U.S. Cl. CPC H01L 25/167; G02B 6/4206; H01L 24/08; H01L 24/32; H10F 39/8063; H01L 23/3135; H01L 23/5385; H10F 39/95

(57) ABSTRACT

A chip structure includes a photonic integrated circuit chip including a waveguide extending in a horizontal direction, an electronic integrated circuit chip on the photonic integrated circuit chip, a silicon block above the photonic integrated circuit chip in a vertical direction and spaced from the electronic integrated circuit chip in the horizontal direction, a first insulating layer at least partially surrounding the electronic integrated circuit chip and the silicon block, and a silicon support on an upper surface of the electronic integrated circuit chip, an upper surface of the silicon block, and an upper surface of the first insulating layer, where the silicon support includes a micro lens, the micro lens is below an upper surface of the silicon support, and the silicon block includes a material that is the same as a material of the silicon support.

### CROSS-REFERENCE TO RELATED APPLICATION

This application is based on and claims priority to Korean Patent Application No. 10-2024-0092587, filed on Jul. 12, 2024, in the Korean Intellectual Property Office, the disclosure of which is incorporated by reference herein in its entirety.

### BACKGROUND

Example embodiments of the disclosure relate to chip structures, and semiconductor packages including the same, and more particularly, to a chip structure including a photonic integrated circuit chip, and a semiconductor package including the same.

With rapid developments in the electronics industry, electronic devices are becoming more compact and lighter. As electronic devices become smaller and lighter, semiconductor packages used in the electronic devices are also becoming smaller and lighter, and the semiconductor packages are required to be highly integrated.

Accordingly, to provide multifunctionality, semiconductor packages are being developed in which various integrated circuits, such as memory chips or logic chips, are mounted on a package substrate. In particular, in an environment where data traffic increases in recent data centers and communication infrastructures, semiconductor packages including photonic integrated circuits are being developed.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a chip structure including a highly-efficient optical engine, and a semiconductor package including the chip structure.

Additional aspects will be set forth in part in the description which follows and, in part, will be apparent from the description, or may be learned by practice of the presented embodiments.

According to an aspect of an example embodiment, a chip structure may include a photonic integrated circuit chip including a waveguide extending in a horizontal direction, an electronic integrated circuit chip on the photonic integrated circuit chip, a silicon block above the photonic integrated circuit chip in a vertical direction and spaced from the electronic integrated circuit chip in the horizontal direction, a first insulating layer at least partially surrounding the electronic integrated circuit chip and the silicon block, and a silicon support on an upper surface of the electronic integrated circuit chip, an upper surface of the silicon block, and an upper surface of the first insulating layer, where the silicon support includes a micro lens, the micro lens is below an upper surface of the silicon support, and the silicon block includes a material that is the same as a material of the silicon support.

According to an aspect of an example embodiment, a semiconductor package may include an interposer substrate, a first semiconductor chip on the interposer substrate, a second semiconductor chip on the interposer substrate and spaced apart from the first semiconductor chip in a horizontal direction, and chip structure on the interposer substrate and spaced apart from the first semiconductor chip and the second semiconductor chip in the horizontal direction, where the chip structure may include a photonic integrated circuit chip including a waveguide extending in the horizontal direction, an electronic integrated circuit chip on the photonic integrated circuit chip, a silicon block above the photonic integrated circuit chip in a vertical direction and spaced from the electronic integrated circuit chip in the horizontal direction, an insulating layer at least partially surrounding the electronic integrated circuit chip and the silicon block, and a silicon support on an upper surface of the electronic integrated circuit chip, an upper surface of the silicon block, and an upper surface of the insulating layer, the silicon support including a micro lens, and where the interposer substrate connects the chip structure to the second semiconductor chip, the silicon block includes a material that is the same as a material of the silicon support, and the micro lens is above the silicon block in the vertical direction and a width of the micro lens in the horizontal direction is within a width of the silicon block in the horizontal direction.

According to an aspect of an example embodiment, a semiconductor package may include a package substrate, an interposer substrate on the package substrate, a first semiconductor chip on the interposer substrate, a second semiconductor chip on the interposer substrate and spaced apart from the first semiconductor chip in a horizontal direction, a chip structure on the interposer substrate and spaced apart from the first semiconductor chip and the second semiconductor chip in the horizontal direction, and a molding member on the interposer substrate and at least partially surrounding the first semiconductor chip, the second semiconductor chip, and the chip structure, where the chip structure may include a photonic integrated circuit chip including a waveguide extending in the horizontal direction, an electronic integrated circuit chip on the photonic integrated circuit chip, a bonding layer between the photonic integrated circuit chip and the electronic integrated circuit chip, the bonding layer including a bonding insulating layer, an upper pad, and a lower pad, a silicon block above the photonic integrated circuit chip in a vertical direction and spaced from the electronic integrated circuit chip in the horizontal direction, a second insulating layer at least partially surrounding the electronic integrated circuit chip and the silicon block, and a silicon support on an upper surface of the electronic integrated circuit chip, an upper surface of the silicon block, and an upper surface of the second insulating layer, the silicon support including a micro lens, and where the interposer substrate connects the chip structure to the second semiconductor chip, the silicon block includes a material that is the same as a material of the silicon support, the upper surface of the second insulating layer is substantially coplanar with the upper surface of the silicon block and the upper surface of the electronic integrated circuit chip, an upper surface of the molding member is substantially coplanar with an upper surface of the first semiconductor chip, an upper surface of the second semiconductor chip, and an upper surface of the chip structure, the micro lens has an upwardly convex shape, and the micro lens is above the silicon block in the vertical direction and a width of the micro lens in the horizontal direction is within a width of the silicon block in the horizontal direction.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view of a semiconductor package according to one or more embodiments;

FIG. 2 is a cross-sectional view of the semiconductor package of FIG. 1 taken along line A1-A1′ according to one or more embodiments;

FIG. 3 is a magnified cross-sectional view of a region AA of FIG. 2 according to one or more embodiments;

FIG. 4 is a magnified cross-sectional view of a region BB of FIG. 3 according to one or more embodiments; and

FIGS. 5 through 14 are cross-sectional views of a method of manufacturing a semiconductor package according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

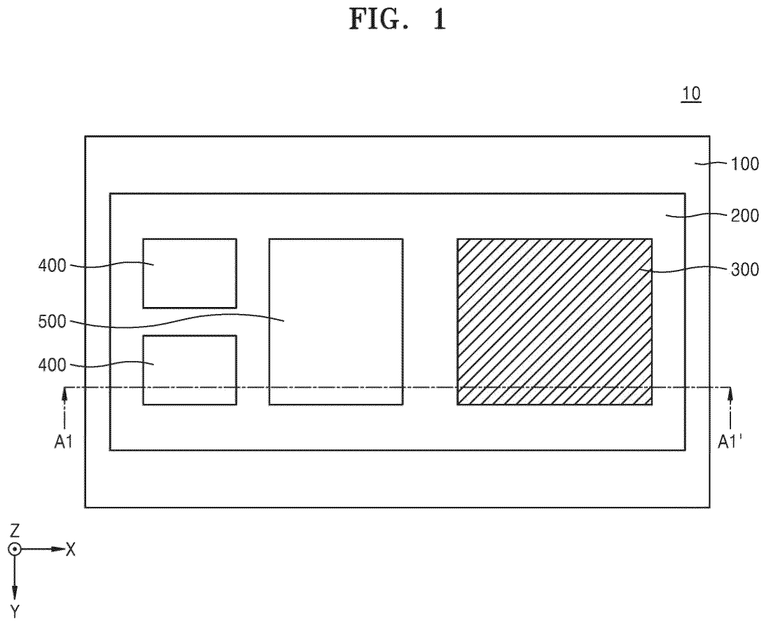

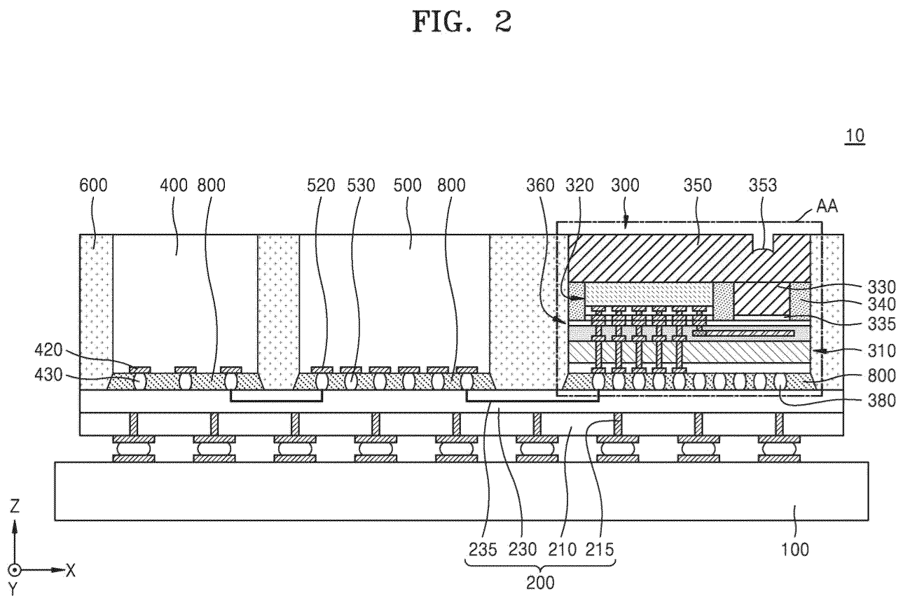

FIG. 1 is a plan view of a semiconductor package 10 according to one or more embodiments. FIG. 2 is a cross-sectional view of the semiconductor package 10 of FIG. 1 taken along line A1-A1′ according to one or more embodiments.

Referring to FIGS. 1 and 2, the semiconductor package 10 may include a package substrate 100, an interposer substrate 200, a chip structure 300, a first semiconductor chip 400, and a second semiconductor chip 500. According to one or more embodiments, the semiconductor package 10 may be a semiconductor package that communicates with an external apparatus via an optical signal. For example, the semiconductor package 10 may be a semiconductor package 10 including a silicon photonics engine.

An X-axis direction and a Y-axis direction represent directions parallel to a surface of the package substrate 100, and the X-axis direction and the Y-axis direction may be understood as directions perpendicular to each other. A Z-axis direction may represent a direction perpendicular to an upper or lower surface of the package substrate 100 (that is, a direction perpendicular to an X-Y plane). A first horizontal direction, a second horizontal direction, and a vertical direction may respectively correspond to the X-axis direction (hereinafter, first horizontal direction X), the Y-axis direction (hereinafter, second horizontal direction Y) and the Z-axis direction (hereinafter, vertical direction Z).

The package substrate 100 may be a substrate on which the interposer substrate 200 is mounted. In one or more embodiments, the package substrate 100 may be a motherboard on which various types of semiconductor chips and packages are mounted. In one or more embodiments, the package substrate 100 may be a substrate that acts as an intermediate bridge of receiving an electrical signal from the interposer substrate 200 and transmitting the electrical signal to an external apparatus.

According to one or more embodiments, the package substrate 100 may be a printed circuit board (PCB) including a wiring pattern and an insulating layer surrounding the wiring pattern. The wiring pattern may be formed of copper, nickel, stainless steel, or beryllium copper, and the insulating layer may be formed of at least one material selected from phenol resin, epoxy resin, and polyimide. For example, an insulating layer may include at least one material selected from among flame retardant 4 (FR4), tetrafunctional epoxy, polyphenylene ether, epoxy/polyphenylene oxide, bismaleimide triazine (BT), thermount, cyanate ester, polyimide, and liquid crystal polymer.

The interposer substrate 200 may be mounted on the package substrate 100. The interposer substrate 200 may be formed based on silicon, and may electrically connect the first semiconductor chip 400, the second semiconductor chip 500, and the chip structure 300 mounted on the interposer substrate 200. In other words, the interposer substrate 200 may serve as a connection passage that electrically connects the first semiconductor chip 400, the second semiconductor chip 500, and the chip structure 300 to each other. According to one or more embodiments, when the first semiconductor chip 400, the second semiconductor chip 500, and the chip structure 300 are different types of chips or chip structures, the first semiconductor chip 400, the second semiconductor chip 500, and the chip structure 300 may exchange electrical signals with each other through the interposer substrate 200.

The interposer substrate 200 may include a wiring layer 230 and a body layer 210. The wiring layer 230 may be located on an upper surface of the body layer 210. A through via 215 may be formed within the body layer 210. The through via 215 may pass through the body layer 210 in the vertical direction Z. According to one or more embodiments, the through via 215 may include a through-silicon via (TSV). The wiring layer 230 may include a wiring pattern 235. The wiring pattern 235 may electrically connect the first semiconductor chip 400, the second semiconductor chip 500, and the chip structure 300 to each other, electrically connect the first semiconductor chip 400 to the through via 215, electrically connect the second semiconductor chip 500 to the through via 215, and electrically connect the chip structure 300 to the through via 215. The through via 215 may be electrically connected to the package substrate 100 via pads and bumps formed on a lower surface of the body layer 210.

According to one or more embodiments, the interposer substrate 200 may be electrically connected to the chip structure 300 through first bumps 380, may be electrically connected to the first semiconductor chip 400 through second bumps 430, and may be electrically connected to the second semiconductor chip 500 through third bumps 530.

The first semiconductor chip 400, the second semiconductor chip 500, and the chip structure 300 may be mounted on the interposer substrate 200. The first semiconductor chip 400 may be mounted on the interposer substrate 200 via the second bumps 430, such as micro-bumps, and the chip pads 420 by using a flip chip method. According to one or more embodiments, an underfill material layer 800 surrounding the second bumps 430 may be disposed between the first semiconductor chip 400 and the interposer substrate 200. The underfill material layer 800 may be formed of, for example, an epoxy resin formed using a capillary under-fill method. However, in one or more embodiments, the molding member 600 may be directly filled into a gap between the first semiconductor chip 400 and the interposer substrate 200 through a molded under-fill process. In this case, the underfill material layer 800 may be omitted.

According to one or more embodiments, the first semiconductor chip 400 may be a memory chip. The memory chip may be, for example, a volatile memory chip, such as dynamic random access memory (DRAM) or static RAM (SRAM), or a non-volatile memory chip, such as phase-change RAM (PRAM), magnetoresistive RAM (MRAM), ferroelectric RAM (FeRAM), or Resistive RAM (RRAM). According to one or more embodiments, the first semiconductor chip 400 may be a high bandwidth memory (HBM) package or wire bonding memory package in which the plurality of the memory chips are stacked in the vertical direction Z.

The second semiconductor chip 500 may be spaced apart from the first semiconductor chip 400 in horizontal directions X and/or Y, and may be mounted on the interposer substrate 200. The second semiconductor chip 500 may be mounted on the interposer substrate 200 via the second bumps 430, such as micro-bumps, and the chip pads 520 by using a flip chip method. According to one or more embodiments, an underfill material layer 800 surrounding the third bumps 530 may be disposed between the second semiconductor chip 500 and the interposer substrate 200. The underfill material layer 800 may be formed of, for example, an epoxy resin formed using a capillary under-fill method. However, in one or more embodiments, the molding member 600 may be directly filled into a gap between the second semiconductor chip 500 and the interposer substrate 200 through a molded under-fill process. In this case, the underfill material layer 800 may be omitted.

According to one or more embodiments, the second semiconductor chip 500 may be a logic chip. The logic chip may be, for example, a microprocessor, such as a central processing unit (CPU), a graphics processing unit (GPU), or an application processor (AP), an analog device, or a digital signal processor.

However, the first semiconductor chip 400 is not limited to a memory chip, and the second semiconductor chip 500 is not limited to a logic chip. In one or more embodiments, each of the first semiconductor chip 400 and the second semiconductor chip 500 may be a memory chip or a logic chip, or the first semiconductor chip 400 may be a logic chip and the second semiconductor chip 500 may be a memory chip.

The chip structure 300 may be spaced apart from the first semiconductor chip 400 and the second semiconductor chip 500 in the horizontal directions X and/or Y, and may be mounted on the interposer substrate 200. In one or more embodiments, the chip structure 300 may be provided spaced apart from the first semiconductor chip 400 along the first horizontal direction X with the second semiconductor chip 500 therebetween. The chip structure 300 may be mounted on the interposer substrate 200 via the first bumps 380, such as micro-bumps, by using a flip chip method. According to one or more embodiments, an underfill material layer 800 surrounding the first bumps 380 may be disposed between the chip structure 300 and the interposer substrate 200. The underfill material layer 800 may be formed of, for example, an epoxy resin formed using a capillary under-fill method. However, in one or more embodiments, the molding member 600 may be directly filled into a gap between the chip structure 300 and the interposer substrate 200 through a molded under-fill process. In this case, the underfill material layer 800 may be omitted.

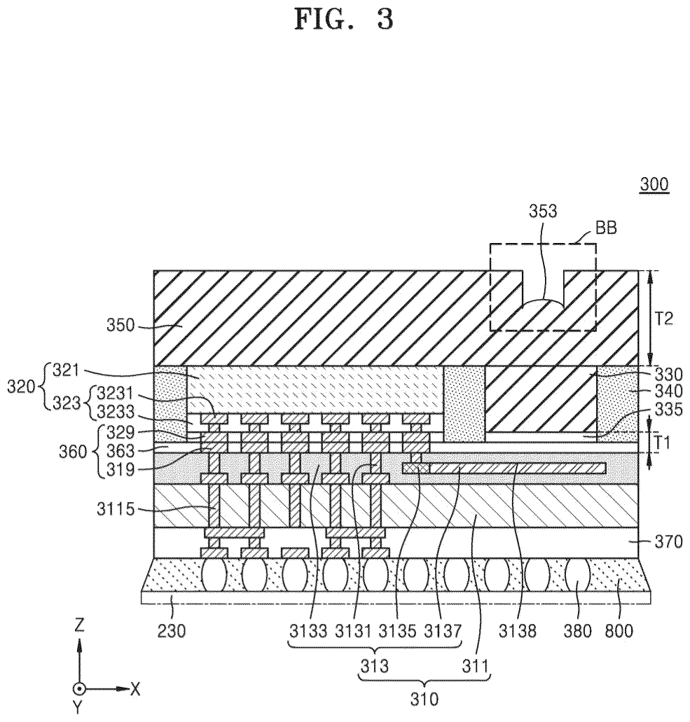

The semiconductor package 10 may communicate with an external apparatus by using an optical signal, through the chip structure 300. The chip structure 300 may receive an optical signal from the external apparatus, convert the received optical signal into an electrical signal, and input the electrical signal into the second semiconductor chip 500 through the interposer substrate 200. The chip structure 300 may be understood as an optical engine. The chip structure 300 may include a photonic integrated circuit (PIC) chip 310, an electronic integrated circuit (EIC) chip 320, a silicon block 330, and a silicon support 350. The chip structure 300 will be described in detail below with reference to FIG. 3.

The molding member 600 may be formed to surround the first semiconductor chip 400, the second semiconductor chip 500, and the chip structure 300 on the upper surface of the interposer substrate 200. In one or more embodiments, the molding member 600 may cover lateral surfaces of each of the first semiconductor chip 400, the second semiconductor chip 500, and the chip structure 300, and may not cover the upper surface of each of the first semiconductor chip 400, the second semiconductor chip 500, and the chip structure 300. An upper surface of the molding member 600 may be substantially coplanar with the upper surfaces of the first semiconductor chip 400, the second semiconductor chip 500, and the chip structure 300. In other words, the upper surface of the molding member 600 may have the same or substantially the same vertical level as the respective upper surfaces of the first semiconductor chip 400, the second semiconductor chip 500, and the chip structure 300. The molding member 600 may be formed to surround the first semiconductor chip 400, the second semiconductor chip 500, and the chip structure 300 on the interposer substrate 200, or may be formed to surround the interposer substrate 200, the first semiconductor chip 400, the second semiconductor chip 500, and the chip structure 300 on the package substrate 100.

According to one or more embodiments, the molding member 600 may be formed from, but is not limited to, a thermosetting resin (such as, an epoxy resin), a thermoplastic resin (such as, a polyimide), or a resin including a reinforcing material, such as an inorganic filler therein. Specifically, the molding member 600 may be formed from an Ajinomoto Build-up Film (ABF), an FR-4, a BT, etc.), and the molding member 600 may be formed from a molding material such as epoxy molding compound (EMC) or a photosensitive material such as a photoimageable encapsulant (PIE). According to one or more embodiments, a portion of the molding member 600 may be formed of an insulating material such as a silicon oxide film, a silicon nitride film, or a silicon oxynitride film.

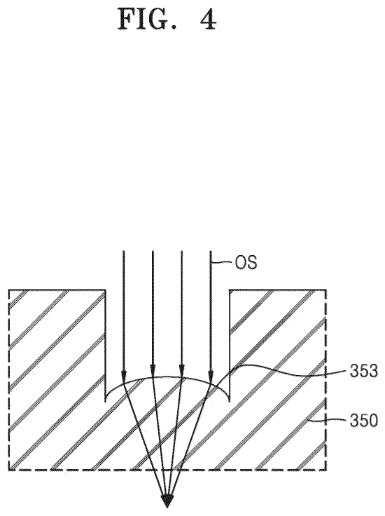

FIG. 3 is a magnified cross-sectional view of a region AA of FIG. 2 according to one or more embodiments. FIG. 4 is a magnified cross-sectional view of a region BB of FIG. 3 according to one or more embodiments. Descriptions of FIGS. 3 and 4 that are the same as or similar to aspects described with reference to FIGS. 1 and 2 may be omitted.

Referring to FIGS. 3 and 4, the chip structure 300 may include a redistribution structure 370, the PIC chip 310, the EIC chip 320, the silicon block 330, the silicon support 350, and the insulating layer 340.

The redistribution structure 370 may be a structure that electrically connects the PIC chip 310 to the interposer substrate 200 of FIG. 2. The redistribution structure 370 may be provided onto the wiring layer 230 of the interposer substrate 200. According to one or more embodiments, the redistribution structure 370 may include a redistribution insulating layer and a redistribution pattern. The redistribution insulating layer may be provided by being stacked along the vertical direction Z, and the redistribution pattern may be provided within the redistribution insulating layer. The redistribution insulating layer may be formed of photo imageable dielectric (PID) or photosensitive polyimide (PSPI), and may include, but is not limited to, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof. In one or more embodiments, the rewiring pattern may be formed by stacking a metal or a metal alloy on a seed layer including copper, titanium, titanium nitride, or titanium tungsten. The PIC chip 310 and the interposer substrate 200 may exchange an electrical signal with each other through the redistribution pattern of the redistribution structure 370.

The PIC chip 310 may include a first substrate 311 and a first wiring structure 313. The first substrate 311 may include a semiconductor material such as silicon or germanium. According to one or more embodiments, the PIC chip 310 may be mounted on the interposer substrate 200 such that the first substrate 311 faces the interposer substrate 200. The PIC chip 310 may be mounted on the interposer substrate 200 via the first bumps 380, by using a flip chip method.

The first wiring structure 313 may include a first wiring pattern 3131, a first wiring insulating layer 3133 surrounding the first wiring pattern 3131, a waveguide 3137, and an optical component 3135. The first wiring pattern 3131 may include a first wiring line extending in the horizontal directions X and/or Y and a first wiring via extending in the vertical direction Z from the first wiring line. The first wiring pattern 3131 may be electrically connected to a through via 3115.

The first wiring insulating layer 3133 may be located on an upper surface of the first substrate 311. According to one or more embodiments, the first wiring insulating layer 3133 may be included as a plurality of layers. For example, the first wiring insulating layer 3133 may be provided as two layers, including a lower wiring insulating layer and an upper wiring insulating layer. In one or more embodiments, the lower wiring insulating layer may be an oxide layer, such as silicon oxide, and the upper wiring insulating layer may be a dielectric layer formed with one or more layers, such as silicon oxide, silicon nitride, or a combination thereof.

A bonding insulating layer 363 and upper pads 319 may be provided on the upper surface of the PIC chip 310. The bonding insulating layer 363 and the upper pads 319 may be located on the upper surface of the first wiring insulating layer 3133. The bonding insulating layer 363 may be formed to surround respective lateral surfaces of the upper pads 319. Respective upper surfaces of the upper pads 319 may be exposed above the bonding insulating layer 363. The upper pads 319 may be electrically connected to the first wiring pattern 3131, and may also be electrically connected to lower pads 329 of the EIC chip 320. The upper pads 319 may be provided in plurality. The EIC chip 320 may vertically overlap the upper pads 319.

The waveguide 3137 may be provided within the first wiring insulating layer 3133. The waveguide 3137, which is a patterned silicon layer, may extend in the first horizontal direction X. In one or more embodiments, the waveguide 3137 may be a silicon waveguide including silicon, and the first wiring insulating layer 3133 may be a buried oxide (BOX) layer. However, embodiments are not limited thereto, and the waveguide 3137 may be covered by an oxide layer that is distinct from the first wiring insulating layer 3133.

The waveguide 3137 may be connected to the optical component 3135. The optical component 3135 may convert an optical signal OS into an electrical signal, and may convert the electrical signal into the optical signal OS. According to one or more embodiments, the optical component 3135 may include a photodetector, a photodiode, and a modulator.

In a process of inputting the optical signal OS to the chip structure 300, the photodetector may detect the optical signal OS input to the PIC chip 310. The PIC chip 310 may detect the optical signal OS input through the photodetector and convert the optical signal OS into an electrical signal.

In a process in which the chip structure 300 outputs the optical signal OS, the EIC chip 320 may transmit the electrical signal to the modulator. The modulator may convert the electrical signal into the optical signal OS by inputting a value corresponding to the received electrical signal to light emitted by the photodiode.

A grating coupler 3138 may be positioned on one side of the waveguide 3137. The PIC chip 310 may receive an aggregated optical signal OS from the silicon support 350 and the silicon block 330 through the grating coupler 3138, or transmit an optical signal OS to the silicon block 330. The grating coupler 3138 may control the direction of the optical signal OS incident through the silicon block 330. That is, a traveling direction of the optical signal OS incident through the silicon block 330 may be changed by the grating coupler 3138, and thus the optical signal OS may move along the waveguide 3137.

The EIC chip 320 may be located on the PIC chip 310. The EIC chip 320 may be configured to interconnect the PIC chip 310 to the first and second semiconductor chips 400 and 500. For example, the EIC chip 320 may convert the electrical signal obtained by the PIC chip 310 so that the electrical signal matches with the first and second semiconductor chips 400 and 500.

According to one or more embodiments, a horizontal width of the EIC chip 320 may be less than a horizontal width of the PIC chip 310. A perimeter of the EIC chip 320 may be less than a perimeter of the PIC chip 310.

The EIC chip 320 may include a second substrate 321 and a second wiring structure 323. The second substrate 321 of the EIC chip 320 may include an active surface and an inactive surface opposite thereto. The second wiring structure 323 may be formed on the active surface of the second substrate 321. The EIC chip 320 may be disposed on the PIC chip 310 such that the active surface of the second substrate 321 faces the PIC chip 310. The second substrate 321 may include a semiconductor material such as silicon or germanium.

According to one or more embodiments, the EIC chip 320 may include a plurality of individual devices used to interface with the PIC chip 310. The plurality of individual devices may be located on the active surface of the second substrate 321. For example, the EIC chip 320 may include complementary metal-oxide-semiconductor (CMOS) drivers, trans-impedance amplifiers, etc. to perform a function such as controlling high-frequency signaling of the PIC chip 310.

The second wiring structure 323 may include a second wiring pattern 3231 and a second wiring insulating layer 3233 surrounding the second wiring pattern 3231. The second wiring pattern 3231 may include a second wiring line extending in the horizontal direction X and a second wiring via extending in the vertical direction Z from the second wiring line. The second wiring pattern 3231 may be electrically connected to the plurality of individual devices and the lower pads 329.

According to one or more embodiments, a bonding layer 360 may be located between the EIC chip 320 and the PIC chip 310. The bonding layer 360 may include the upper pads 319, the lower pads 329, and the bonding insulating layer 363. The upper pads 319 may be pads positioned on the upper surface of the PIC chip 310, and the lower pads 329 may be pads positioned on the lower surface of the EIC chip 320. The EIC chip 320 and the PIC chip 310 may be electrically connected to each other by the bonding layer 360 positioned between the EIC chip 320 and the PIC chip 310.

The EIC chip 320 and the PIC chip 310 may be coupled to each other by direct bonding. The direct bonding may include dielectric-to-dielectric bonding, copper (Cu)—Cu bonding, and hybrid bonding in which dielectric-to-dielectric bonding and metal-to-metal bonding occur together. The direct bonding may be diffusion bonding in which two interfaces including the same material are placed opposite to each other, then brought into contact with each other and are heated so that metal atoms or dielectric materials in contact with each other are integrated with each other via diffusion.

According to one or more embodiments, the bonding layer 360 may be formed by diffusing and bonding the upper pad 319 of the PIC chip 310 and the lower pad 329 of the EIC chip 320 by using heat, and diffusing and bonding the insulating layer surrounding the upper pad 319 of the PIC chip 310 and the insulating layer surrounding the lower pad 329 of the EIC chip 320 by using heat.

Coupling of the EIC chip 320 and the PIC chip 310 is not limited thereto, and the EIC chip 320 and the PIC chip 310 may be electrically connected to each other by a connection terminal, such as solder balls, or an adhesive film, such as an anisotropic film (ACF) or a non-conductive film (NCF).

The silicon block 330 may be located over the PIC chip 310 (i.e., above the PIC chip 310 in the vertical direction Z). The silicon block 330 may be spaced apart from the EIC chip 320 in the horizontal directions X and/or Y. In one or more embodiments, the silicon block 330 may be spaced apart from the upper surface of the PIC chip 310 in the vertical direction Z. An oxide layer 335 may be provided on the lower surface of the silicon block 330. According to one or more embodiments, the oxide layer 335 may be a silicon oxide layer (SiO₂). The oxide layer 335 may be formed in a flat shape on the lower surface of the silicon block 330. When the silicon block 330 is provided at a predetermined interval apart from the upper surface of the PIC chip 310, a distance T1 between the lower surface of the silicon block 330 and the upper surface of the first wiring insulating layer 3133 of the PIC chip 310 in the vertical direction Z may be 1.5 μm or less. In other words, the distance T1 between the upper surface of the oxide layer 335 of the silicon block 330 and the upper surface of the first wiring insulating layer 3133 of the PIC chip 310 in the vertical direction Z may be 1.5 μm or less. According to one or more embodiments, the distance T1 between the lower surface of the silicon block 330 and the upper surface of the first wiring insulating layer 3133 of the PIC chip 310 in the vertical direction Z may be in a range of 1 μm to 1.5 μm. In other words, the distance T1 between the upper surface of the oxide layer 335 of the silicon block 330 and the upper surface of the first wiring insulating layer 3133 of the PIC chip 310 in the vertical direction Z may be in a range of 1 μm to 1.5 μm. In one or more embodiments, the oxide layer 335 and the bonding insulating layer 363 may form an interface in the vertical direction Z as illustrated in FIG. 3. However, embodiments are not limited thereto, and the oxide layer 335 and the bonding insulating layer 363 may be integrally bonded to each other during a bonding process so that an interface between the oxide layer 335 and the bonding insulating layer 363 may not be formed. In one or more embodiments, the oxide layer 335 and the bonding insulating layer 363 may be formed of the same material as the insulating layer 340 so that no interfaces appear between the oxide layer 335, the bonding insulating layer 363, and the insulating layer 340.

In one or more embodiments, the silicon block 330 may be provided on the upper surface of the PIC chip 310. A horizontal width of the silicon block 330 may be less than a horizontal width of the PIC chip 310.

The silicon block 330 may be located over the waveguide 3137 of the PIC chip 310 and the grating coupler 3138. An optical path through which an external optical signal OS is transmitted to the PIC chip 310 may be formed inside the silicon block 330.

According to one or more embodiments, the silicon block 330 may be made of the same material as the silicon support 350. Accordingly, as the optical signal OS passes through the silicon block 330, the refractive index remains the same, which may reduce optical reflection and decrease optical loss.

The insulating layer 340 may be provided to surround the EIC chip 320 and the silicon block 330. The insulating layer 340 may include silicon oxide (SiO₂). The insulating layer 340 may be formed by using a plasma-enhanced chemical vapor deposition (PECVD) method. According to one or more embodiments, the upper surface of the insulating layer 340 may be substantially coplanar with the upper surface of the EIC chip 320 and the upper surface of the silicon block 330. In other words, the upper surface of the insulating layer 340 may be at the same or substantially the same vertical level as the upper surface of the EIC chip 320 and the upper surface of the silicon block 330.

The silicon block 330 may be formed of silicon, and may be formed of substantially the same material as the silicon support 350. The silicon block 330 may be coupled to an upper surface of the PIC chip 310 by oxide bonding. However, embodiments are not limited thereto, and the silicon block 330 may be attached to the upper surface of the PIC chip 310 via an optical adhesive layer.

The silicon support 350 may be located on the upper surface of the silicon block 330 and the upper surface of the EIC chip 320. The upper surface of the silicon block 330 and the upper surface of the EIC chip 320 may be on the same or substantially the same vertical level as each other. When the upper surface of the silicon block 330 and the upper surface of the EIC chip 320 are at different vertical levels, the lower surface of the silicon support 350 may have a staircase shape, and thus the lower surface of the silicon support 350 and the upper surface of the silicon block 330 may contact each other, and at the same time, the lower surface of the silicon support 350 and the upper surface of the EIC chip 320 may contact each other.

The silicon support 350 may be formed of substantially the same material as the silicon block 330. For example, the silicon support 350 may be formed of silicon. The silicon support 350 may be understood as dummy silicon. A thickness T2 of the silicon support 350 in the vertical direction Z may be in a range of 700 μm to 800 μm. The upper surface of the silicon support 350 may be substantially coplanar with the upper surface of the molding member 600 of FIG. 2. In other words, the upper surface of the silicon support 350 may be substantially at the same level as the upper surface of the molding member 600.

The silicon support 350 may include a micro lens 353. The micro lens 353 may be formed by etching the silicon support 350. The micro lens 353 may be formed by etching the silicon support 350 to a certain depth and then etching an etched surface of the silicon support 350 again into a convex shape. Accordingly, the micro lens 353 may be understood as a convexly etched surface of the silicon support 350. Thus, the micro lens 353 may be formed below the upper surface of the silicon support 350.

According to one or more embodiments, the micro lens 353 may have an upwardly convex shape. Accordingly, the focus of the micro lens 353 may be located inside the silicon support 350 or the silicon block 330. According to one or more embodiments, the micro lens 353 may be positioned vertically above silicon block 330, such that a width of the micro lens 353 in a horizontal direction is within a width of the silicon block 330 in the horizontal direction.

The micro lens 353 may be exposed from the silicon support 350. In other words, the convexly etched surface of the silicon support 350 may be exposed to the outside, and the optical signal OS may be emitted to the micro lens 353 as shown in FIG. 4. The optical signal OS emitted to the micro lens 353 may be refracted and converged by the curvature of the micro lens 353. Because the micro lens 353 has an upwardly convex shape, the optical signal OS emitted to the micro lens 353 may be converged to one point. The optical signal OS may be emitted to the micro lens 353 of the silicon support 350, may pass through the inside of the silicon block 330, and may be transmitted to the waveguide 3137 of the PIC chip 310.

Because the micro lens 353 is formed by etching the silicon support 350, there is no need for the chip structure 300 to include a new micro lens (e.g., to include an additional micro lens formed on a surface thereof). In addition, because the upper surface of the silicon support 350 is not covered by the molding member 600, the silicon support 350 may function as a heat dissipation member. Accordingly, the heat dissipation characteristics of the chip structure 300 and the semiconductor package 10 may be improved.

In addition, because the optical signal OS is emitted to the micro lens 353 of the silicon support 350, passes through the inside of the silicon block 330, and is transmitted to the waveguide 3137 of the PIC chip 310, and the silicon support 350 and the silicon block 330 are composed of the same material, optical loss due to optical reflection that occurs as the optical signal OS moves may be minimized. Moreover, as described below, because the insulating layer 340 is formed after the silicon block 330 is formed, the upper surface of the insulating layer 340 may be flattened.

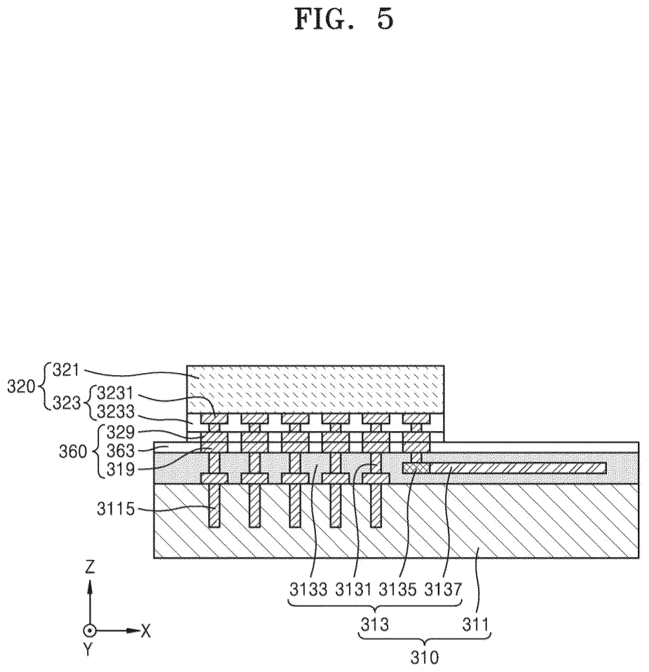

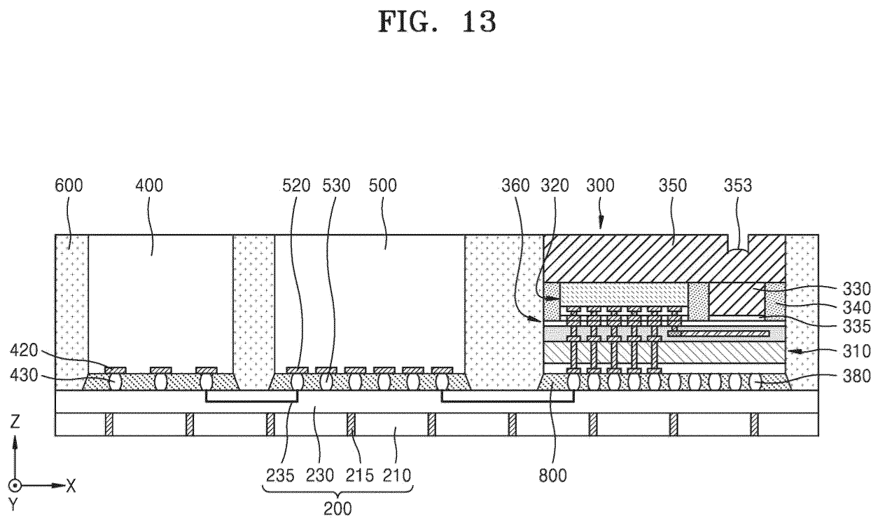

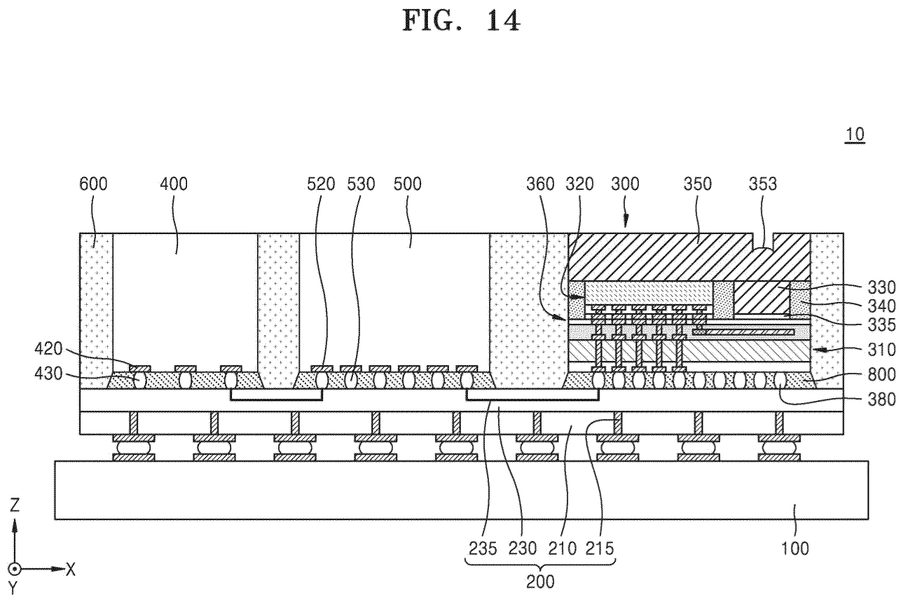

FIGS. 5 to 14 are cross-sectional views illustrating a method of manufacturing a semiconductor package according to one or more embodiments. Descriptions of FIGS. 5 through 14 that are the same as or similar to aspects described with reference to FIGS. 1 through 4 may be omitted.

First, referring to FIG. 5, the PIC chip 310 may be prepared, and the EIC chip 320 may be attached onto the PIC chip 310. The PIC chip 310 may include the first substrate 311, and the first wiring structure 313 located on the upper surface of the first substrate 311. The through via 3115 may extend inside the first substrate 311 and may be connected to the first wiring structure 313. The EIC chip 320 may be attached onto the PIC chip 310 in a face-down manner such that the second wiring structure 323 of the EIC chip 320 faces the first wiring structure 313 of the PIC chip 310.

According to one or more embodiments, the PIC chip 310 and the EIC chip 320 may be coupled to each other by hybrid bonding. The bonding layer 360 may be formed by the hybrid bonding. The bonding layer 360 may be formed by bonding the upper pad 319 of the PIC chip 310 to the lower pad 329 of the EIC chip 320 by hybrid bonding and bonding the first wiring insulating layer 3133 to the second wiring insulating layer 3233 by hybrid bonding. The PIC chip 310 and the EIC chip 320 may be electrically connected to each other by the bonding layer 360.

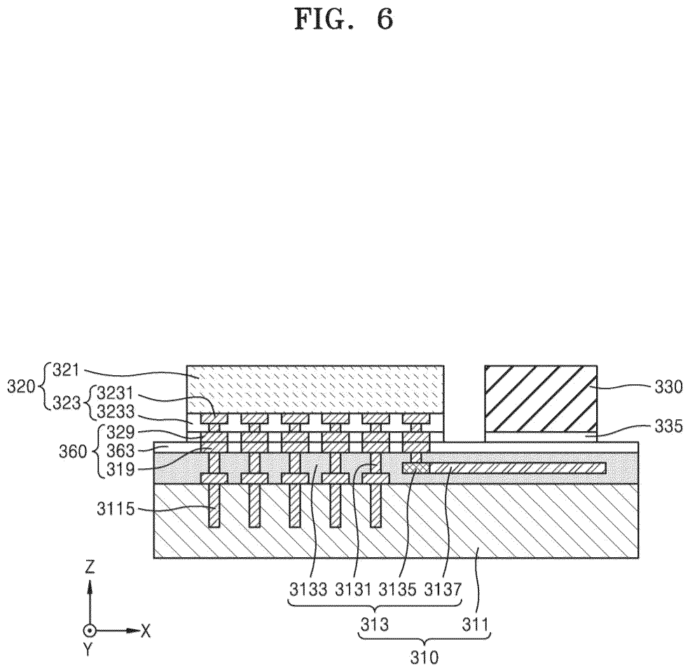

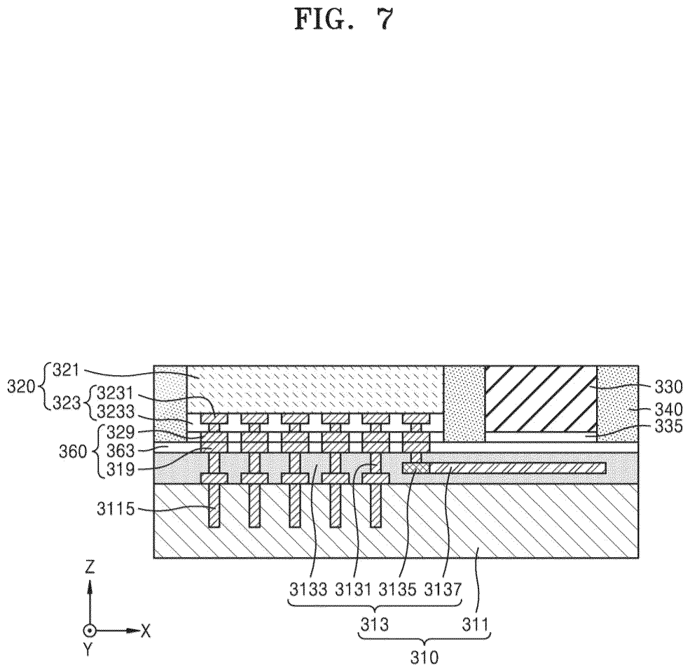

Referring to FIGS. 6 and 7, the silicon block 330 may be attached onto the PIC chip 310. The oxide layer 335 may be provided on the lower surface of the silicon block 330. The silicon block 330 may be coupled to the upper surface of the PIC chip 310 by oxide bonding. The oxide bonding may be a process used when two silicon wafers or other semiconductor devices are bonded with each other. In the oxide bonding, thin oxide layers may be formed on respective surfaces of silicon wafers or other semiconductor devices, and may be bonded with each other to thereby form a strong bond. In detail, the oxide layer 335 of the silicon block 330 may be bonded to the bonding insulating layer 363 of the PIC chip 310 through oxide bonding. As illustrated in FIG. 6, an interface between the oxide layer 335 and the bonding insulating layer 363 in the vertical direction Z may be formed between the oxide layer 335 and the bonding insulating layer 363. However, embodiments are not limited thereto, and the oxide layer 335 and the bonding insulating layer 363 may be integrally bonded to each other during a bonding process so that an interface may not be formed between the oxide layer 335 and the bonding insulating layer 363. Thereafter, the insulating layer 340 may be formed on the PIC chip 310. The insulating layer 340 may be formed to surround the EIC chip 320 and the silicon block 330. The insulating layer 340 may be formed through a PECVD process after the silicon block 330 is formed. When the insulating layer 340 is formed by a PECVD process, in the case that there are no silicon blocks 330, only the EIC chip 320 protrudes above the PIC chip 310 in the vertical direction Z, and a height of the upper surface of the insulating layer 340 may be relatively irregular. For example, a vertical level of the insulating layer 340 formed on the upper surface of the EIC chip 320 may be different from that of the insulating layer 340 formed on the upper surface of the PIC chip 310. The vertical level of the insulating layer 340 formed on the upper surface of the EIC chip 320 may be greater than that of the insulating layer 340 formed on the upper surface of the PIC chip 310. Accordingly, an overall shape of the insulating layer 340 may be an uneven shape. However, when the silicon block 330 is formed on the upper surface of the PIC chip 310 and then the insulating layer 340 is formed through a PECVD process, the insulating layer 340 may be provided in a state where its upper surface may be relatively flattened.

After the formation of the insulating layer 340, the EIC chip 320, the silicon block 330, and the insulating layer 340 may be formed to desired thicknesses through a grinding or chemical mechanical polishing (CMP) process. After the grinding or CMP process, the upper surface of the insulating layer 340 may be formed to be coplanar with the upper surface of the EIC chip 320 and the upper surface of the silicon block 330.

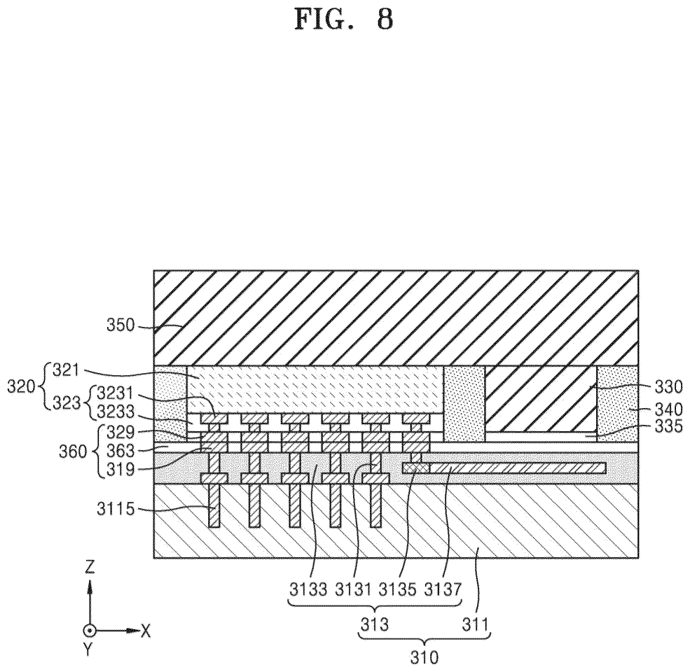

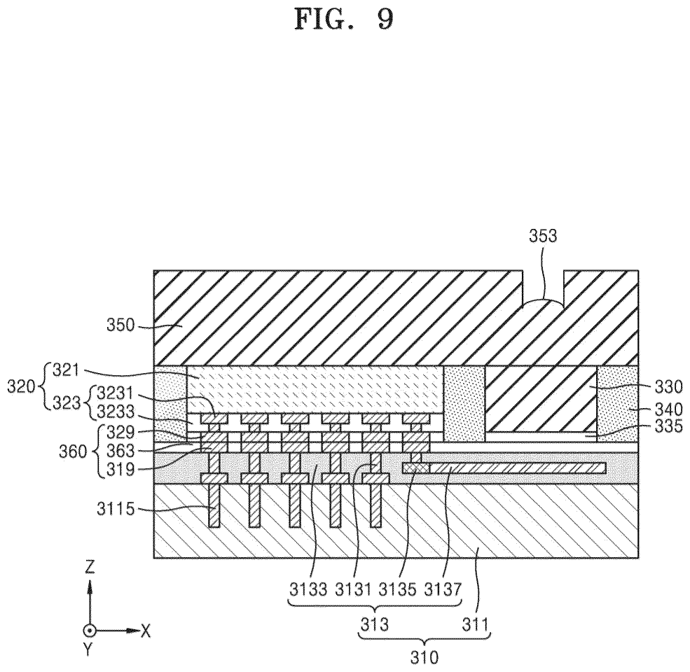

Referring to FIGS. 8 and 9, the silicon support 350 may be attached to the respective upper surfaces of the insulating layer 340, the EIC chip 320, and the silicon block 330 that are coplanar with each other. The silicon support 350 may be attached to the respective upper surfaces of the insulating layer 340, the EIC chip 320, and the silicon block 330 via oxide bonding. The oxide bonding may be wafer-to-wafer oxide bonding.

After the silicon support 350 is attached to the respective upper surfaces of the insulating layer 340, the EIC chip 320, and the silicon block 330, the silicon support 350 may be etched to form the micro lens 353. The micro lens 353 may be formed by etching the upper surface of the silicon support 350 to a certain depth and then etching the surface of an etched portion of the silicon support 350 again such that the surface of the etched portion is upwardly convex. The micro lens 353 may have an upwardly convex shape. The micro lens 353 may be formed such that the external optical signal OS may pass through the silicon support 350 and the silicon block 330 and may be transmitted to the waveguide 3137 of the PIC chip 310.

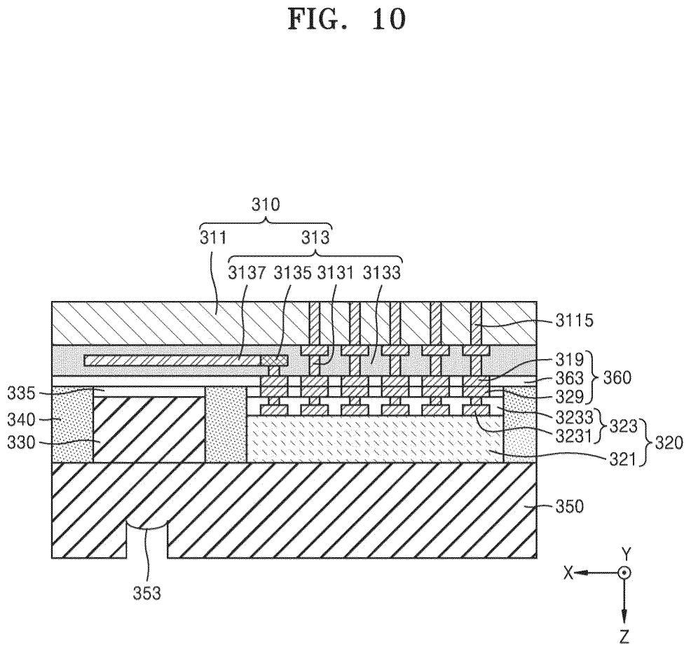

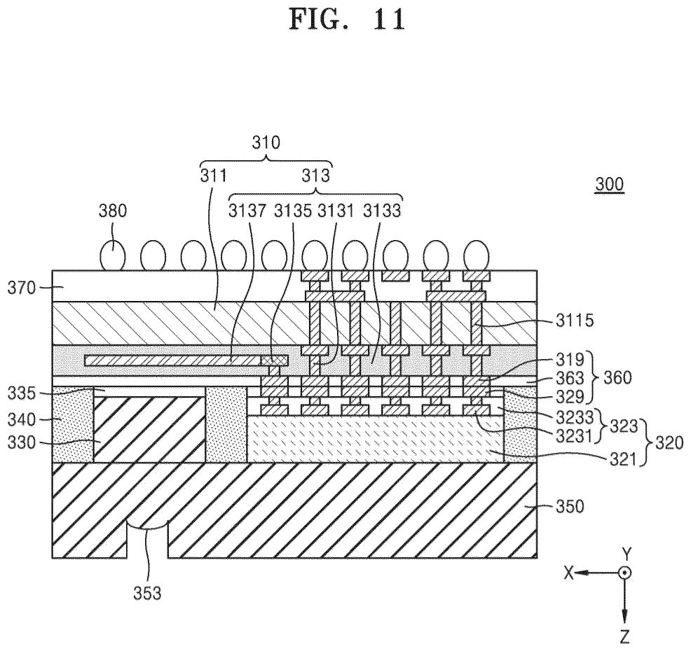

Referring to FIGS. 10 and 11, a chip structure of FIG. 9 may be turned over, and the first substrate 311 of the PIC chip 310 may be ground such that the through via 3115 is exposed from the first substrate 311. A process of grinding the first substrate 311, which is a back grinding process, may be understood as a process of thinning the first substrate 311. When the through via 3115 is exposed from the first substrate 311, the redistribution structure 370 may be formed on the first substrate 311. The redistribution structure 370 may include a redistribution insulating layer and a redistribution pattern, and the redistribution pattern may be connected to the exposed through via 3115. After that, the first bumps 380 are formed on the redistribution structure 370.

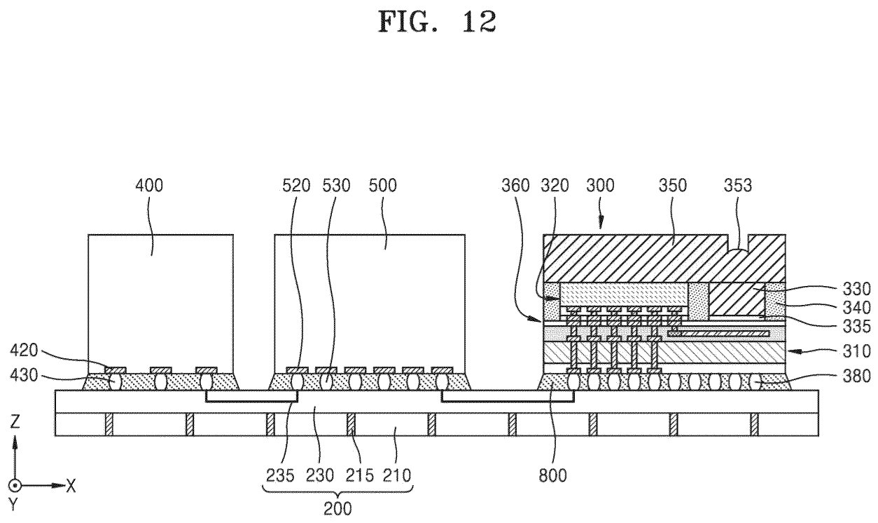

Referring to FIGS. 12 through 14, the first semiconductor chip 400, the second semiconductor chip 500, and the chip structure 300 of FIG. 12 may be mounted on the interposer substrate 200. The chip structure 300 may be mounted on the interposer substrate 200 such that the first bumps 380 face the upper surface of the wiring layer 230 of the interposer substrate 200. The first semiconductor chip 400 and the second semiconductor chip 500 may be mounted on the interposer substrate 200 simultaneously when the chip structure 300 is mounted on the interposer substrate 200. Then, the molding member 600 may be formed on the interposer substrate 200. The molding member 600 may cover each of the first semiconductor chip 400, the second semiconductor chip 500, and the chip structure 300. According to one or more embodiments, the respective upper surfaces of the first semiconductor chip 400, the second semiconductor chip 500, and the chip structure 300 may be exposed from the molding member 600. Then, the interposer substrate 200 may be mounted on the package substrate 100.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A chip structure comprising:
a photonic integrated circuit chip comprising a waveguide extending in a horizontal direction;
an electronic integrated circuit chip on the photonic integrated circuit chip;
a silicon block above the photonic integrated circuit chip in a vertical direction and spaced from the electronic integrated circuit chip in the horizontal direction;
a first insulating layer at least partially surrounding the electronic integrated circuit chip and the silicon block; and
a silicon support on an upper surface of the electronic integrated circuit chip, an upper surface of the silicon block, and an upper surface of the first insulating layer,
wherein the silicon support comprises a micro lens,
wherein the micro lens is below an upper surface of the silicon support, and
wherein the silicon block comprises a material that is the same as a material of the silicon support.

2. The chip structure of claim 1, wherein the upper surface of the silicon block directly contacts a lower surface of the silicon support.

3. The chip structure of claim 2, wherein the silicon block is oxide-bonded to the silicon support.

4. The chip structure of claim 1, further comprising a second insulating layer between the silicon block and the photonic integrated circuit chip.

5. The chip structure of claim 4, wherein, in the vertical direction, a distance between a lower surface of the silicon block and an upper surface of the photonic integrated circuit chip is in a range of 1 μm to 1.5 μm.

6. The chip structure of claim 1, wherein the photonic integrated circuit chip is hybrid-bonded to the electronic integrated circuit chip.

7. The chip structure of claim 1, further comprising a bonding layer between the photonic integrated circuit chip and the electronic integrated circuit chip,
wherein the bonding layer comprises a bonding insulating layer, an upper pad, and a lower pad.

8. The chip structure of claim 1, wherein the silicon block is oxide-bonded to the photonic integrated circuit chip.

9. The chip structure of claim 1, wherein, in the vertical direction, a thickness of the silicon support is in a range of 700 μm to 800 μm.

10. The chip structure of claim 1, wherein the micro lens is above the silicon block in the vertical direction and a width of the micro lens in the horizontal direction is within a width of the silicon block in the horizontal direction.

11. A semiconductor package comprising:
an interposer substrate;
a first semiconductor chip on the interposer substrate;
a second semiconductor chip on the interposer substrate and spaced apart from the first semiconductor chip in a horizontal direction; and
a chip structure on the interposer substrate and spaced apart from the first semiconductor chip and the second semiconductor chip in the horizontal direction,
wherein the chip structure comprises:
a photonic integrated circuit chip comprising a waveguide extending in the horizontal direction;
an electronic integrated circuit chip on the photonic integrated circuit chip;
a silicon block above the photonic integrated circuit chip in a vertical direction and spaced from the electronic integrated circuit chip in the horizontal direction;
an insulating layer at least partially surrounding the electronic integrated circuit chip and the silicon block; and
a silicon support on an upper surface of the electronic integrated circuit chip, an upper surface of the silicon block, and an upper surface of the insulating layer, the silicon support comprising a micro lens,
wherein the interposer substrate connects the chip structure to the second semiconductor chip,
wherein the silicon block comprises a material that is the same as a material of the silicon support, and
wherein the micro lens is above the silicon block in the vertical direction and a width of the micro lens in the horizontal direction is within a width of the silicon block in the horizontal direction.

12. The semiconductor package of claim 11, wherein the micro lens is below an upper surface of the silicon support.

13. The semiconductor package of claim 12, wherein the micro lens has an upwardly convex shape.

14. The semiconductor package of claim 11, further comprising a molding member on the interposer substrate and at least partially surrounding the first semiconductor chip, the second semiconductor chip, and the chip structure,
wherein an upper surface of the molding member is substantially coplanar with an upper surface of the first semiconductor chip, an upper surface of the second semiconductor chip, and an upper surface of the chip structure.

15. The semiconductor package of claim 11, further comprising a bonding layer between the photonic integrated circuit chip and the electronic integrated circuit chip,
wherein the bonding layer comprises a bonding insulating layer, an upper pad, and a lower pad.

16. The semiconductor package of claim 11, wherein the silicon block is oxide-bonded to the silicon support.

17. The semiconductor package of claim 11, wherein the first semiconductor chip comprises a memory chip and the second semiconductor chip comprises a logic chip.

18. A semiconductor package comprising:
a package substrate;
an interposer substrate on the package substrate;
a first semiconductor chip on the interposer substrate;
a second semiconductor chip on the interposer substrate and spaced apart from the first semiconductor chip in a horizontal direction;
a chip structure on the interposer substrate and spaced apart from the first semiconductor chip and the second semiconductor chip in the horizontal direction; and
a molding member on the interposer substrate and at least partially surrounding the first semiconductor chip, the second semiconductor chip, and the chip structure,
wherein the chip structure comprises:
a photonic integrated circuit chip comprising a waveguide extending in the horizontal direction;
an electronic integrated circuit chip on the photonic integrated circuit chip;
a bonding layer between the photonic integrated circuit chip and the electronic integrated circuit chip, the bonding layer comprising a bonding insulating layer, an upper pad, and a lower pad;
a silicon block above the photonic integrated circuit chip in a vertical direction and spaced from the electronic integrated circuit chip in the horizontal direction;
a second insulating layer at least partially surrounding the electronic integrated circuit chip and the silicon block; and
a silicon support on an upper surface of the electronic integrated circuit chip, an upper surface of the silicon block, and an upper surface of the second insulating layer, the silicon support comprising a micro lens,
wherein the interposer substrate connects the chip structure to the second semiconductor chip,
wherein the silicon block comprises a material that is the same as a material of the silicon support,
wherein the upper surface of the second insulating layer is substantially coplanar with the upper surface of the silicon block and the upper surface of the electronic integrated circuit chip,
wherein an upper surface of the molding member is substantially coplanar with an upper surface of the first semiconductor chip, an upper surface of the second semiconductor chip, and an upper surface of the chip structure,
wherein the micro lens has an upwardly convex shape, and
wherein the micro lens is above the silicon block in the vertical direction and a width of the micro lens in the horizontal direction is within a width of the silicon block in the horizontal direction.

19. The semiconductor package of claim 18, further comprising a redistribution structure between the photonic integrated circuit chip and the interposer substrate.

20. The semiconductor package of claim 18, wherein, in the vertical direction, a distance between a lower surface of the silicon block and an upper surface of the photonic integrated circuit chip is in a range of 1 μm to 1.5 μm, and
wherein a thickness of the silicon support in the vertical direction is in a range of 700 μm to 800 μm.
